(19) United States
(12) Patent Application Publication
(10) Pub. No.: US 2026/0090345 A1
(43) Pub. Date: Mar. 26, 2026

(54) SEMICONDUCTOR STRUCTURE WITH ISOLATION STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Sheng-Chieh CHEN, Hsinchu (TW); Chern-Yow HSU, Hsinchu (TW); Hung-Ling SHIH, Hsinchu (TW); Yun-Chi WU, Hsinchu (TW)

(73) Assignee: TAIWAN SEMICONDUCTOR MANUFACTURING COMPANY, LTD., Hsinchu (TW)

(21) Appl. No.: 18/898,126

(22) Filed: Sep. 26, 2024

(51) Int. Cl. H01L 21/762; H01L 29/06; H01L 29/66; H01L 29/78

(52) U.S. Cl. CPC H10P 90/1906; H10D 30/0281; H10D 30/657; H10D 62/116; H10W 10/041; H10W 10/061; H10W 10/181; H10W 10/40

(57) ABSTRACT

A method for manufacturing a semiconductor structure includes: forming a trench in a semiconductor substrate; forming an isolating material layer on the semiconductor substrate and in the trench; forming a protective material layer on the isolating material layer and in the trench; removing horizontal portions of the protective material layer to form a protective layer laterally covering the isolating material layer and to expose horizontal portions of the isolating material layer from the protective layer; removing the horizontal portions of the isolating material layer to form an isolation layer that laterally covers the semiconductor substrate and that is disposed between the protective layer and the semiconductor substrate; and forming a conductive material layer to fill the trench.

### BACKGROUND

A bipolar-CMOS (complementary metal oxide semiconductor)-DMOS (double diffused metal oxide semiconductor) (BCD) device, which includes bipolar, CMOS, and DMOS devices in one semiconductor chip, has been applied in a high voltage power device. In order to meet more application needs, improvement on device performance of the BCD device is required. At present, the BCD device faces some issues (e.g., leakage, electrical breakdown, etc.) which need to be solved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 9B are schematic views illustrating intermediate stages of the manufacturing method in accordance with some embodiments as depicted in FIG. 1.

FIGS. 10A to 10C are schematic views illustrating a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain region(s)” may refer to a source or a drain, individually or collectively dependent upon the context.

A bipolar-CMOS (complementary metal oxide semiconductor)-DMOS (double diffused metal oxide semiconductor) (BCD) device is an important component in a high voltage power device. A BCD device includes a semiconductor substrate, a high voltage region, a low voltage region, an N-type well region, a P-type well region, and a deep trench isolation (DTI) structure. In the BCD device, the high voltage region and the low voltage region are separated by the DTI structure, the N-type well region surrounds the high voltage region, and the P-type well region is located between the N-type well region and the DTI structure in a first direction (e.g., an X direction). The DTI structure includes a conductive layer and an isolation layer that surrounds the conductive layer and that has a cross section that may have a tapered shape (caused by an etching process). When the BCD device operates under a high voltage (e.g., about 120 V), charged carriers in the high voltage region may pass through the DTI structure to the low voltage region along a short path (without passing through the P-type well region in a second direction (e.g., a Y direction) transverse to the first direction), resulting in a leakage and an electrical breakdown (an increased breakdown voltage (Vbd)) in the BCD device. In this case, the isolation layer of the DTI structure may not be able to efficiently provide a good isolation for preventing the charged carriers from passing therethrough.

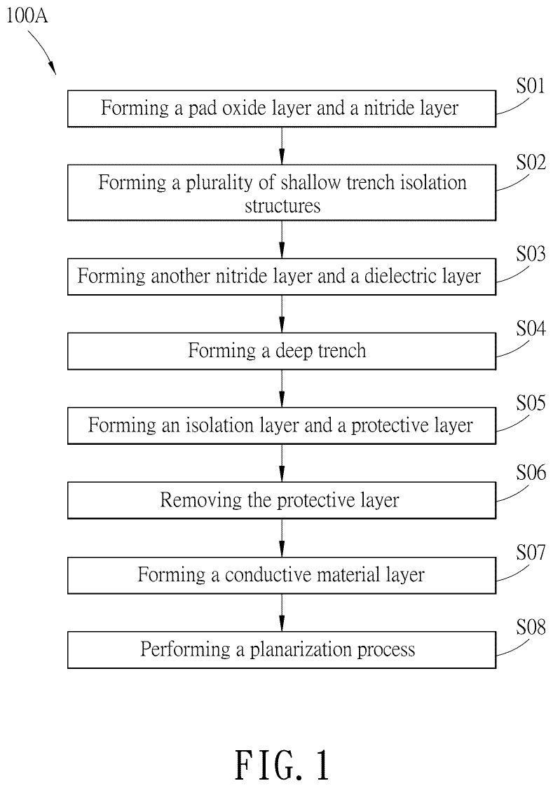

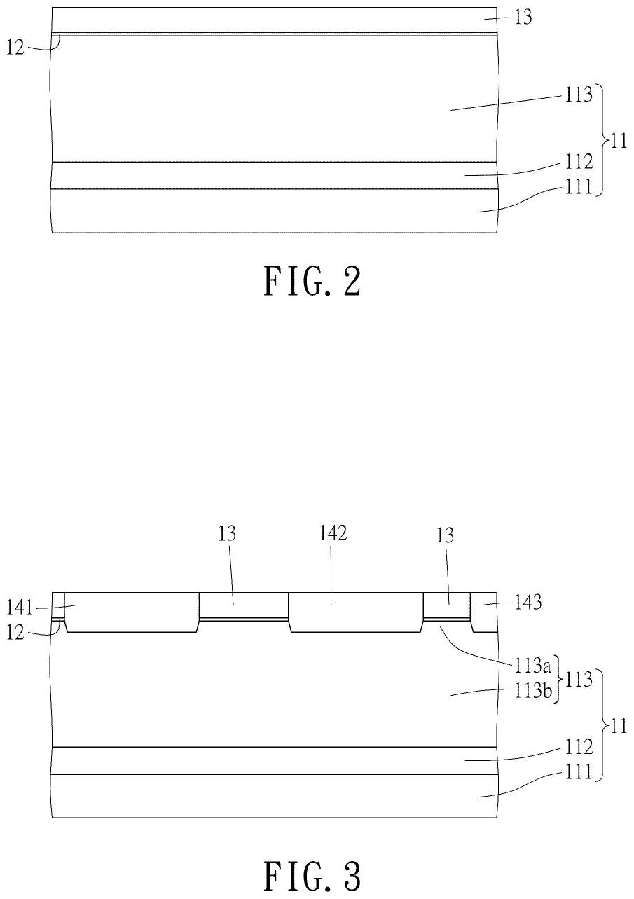

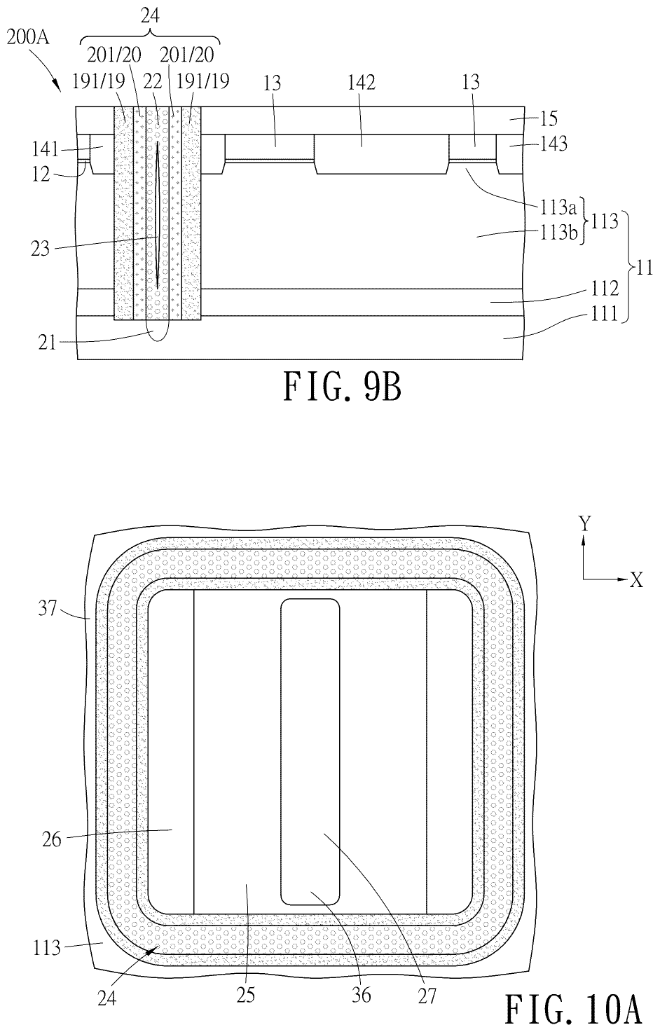

The present disclosure is directed to a semiconductor structure and a method for manufacturing the same. FIG. 1 is a flow diagram illustrating a method 100A for manufacturing a semiconductor structure 200A shown in FIG. 9A or 9B in accordance with some embodiments. FIGS. 2 to 8 illustrate schematic views of some intermediate stages of the method 100A. Some portions may be omitted in FIGS. 2 to 8 for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where a pad oxide layer 12 and a nitride layer 13 are sequentially formed on a semiconductor substrate 11.

The semiconductor substrate 11 may include a lower semiconductor layer 111, a buried insulation layer 112 (e.g., a buried oxide (BOX) layer), and an upper semiconductor layer 113. In some embodiments, the semiconductor substrate 11 may be, for example, but not limited to, a part of a silicon-on-insulator (SOI) substrate or an SOS (silicon-on-sapphire) substrate. Other suitable substrates are also within the contemplated scope of the present disclosure. In some embodiments, the lower semiconductor layer 111 may be an elemental semiconductor or a compound semiconductor. The elemental semiconductor may be composed of single species of atoms, such as silicon and germanium in column 14 of the periodic table, or other suitable materials. The compound semiconductor may be composed of two or more elements, such as silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, gallium indium arsenide phosphide, or other suitable materials. In some embodiments, the lower semiconductor layer 111 and the upper semiconductor layer 113 may be made of the same material.

The buried insulation layer 112 is disposed between the lower semiconductor layer 111 and the upper semiconductor layer 113. In some embodiments, the buried insulation layer 112 may be made of, for example, but not limited to, silicon oxide. Other suitable materials for the buried insulation layer 112 are also within the contemplated scope of the present disclosure. In some embodiments, the buried insulation layer 112 may be formed by, for example, but not limited to, SOI techniques, such as implanted oxygen techniques (SIMOX), or bonded-and-etch-back SOI (BESOI) techniques. Other suitable techniques for forming the buried insulation layer 112 are also within the contemplated scope of the present disclosure.

The pad oxide layer 12 is formed over the upper semiconductor layer 113 opposite to the buried insulation layer 112. In some embodiments, the pad oxide layer 12 may include, for example, but not limited to, silicon oxide. Other suitable materials for the pad oxide layer 12 are also within the contemplated scope of the present disclosure. In some embodiments, the pad oxide layer 12 may be formed by a suitable deposition process, for example, but not limited to, chemical vapor deposition (CVD), physical vapor deposition (PVD), or atomic layer deposition (ALD). Other suitable processes for forming the pad oxide layer 12 are also within the contemplated scope of the present disclosure. In some alternative embodiments, the pad oxide layer 12 may be formed by thermally oxidizing the upper semiconductor layer 113 in an oxygen-containing atmosphere.

The nitride layer 13 is disposed on the pad oxide layer 12 opposite to the upper semiconductor layer 113 of the semiconductor substrate 11. In some embodiments, the nitride layer 13 may include, for example, but not limited to, silicon nitride. Other suitable materials for forming the nitride layer 13 are also within the contemplated scope of the present disclosure. In some embodiments, the nitride layer 13 may be formed by a suitable deposition process, for example, but not limited to, CVD, PVD, or ALD. Other suitable processes for forming the nitride layer 13 are also within the contemplated scope of the present disclosure.

Referring to FIG. 1 and the example illustrated in FIG. 3, the method 100A then proceeds to step S02, where a plurality of shallow trench isolation (STI) structures 141, 142, 143 are formed in the structure shown in FIG. 2 and are spaced apart from each other. In some embodiments, the STI structures 141, 142, 143 are located at a first substrate portion 113a of the upper semiconductor layer 113. In some embodiments, the upper semiconductor layer 113 may include the first substrate portion 113a which has a top surface of the upper semiconductor layer 113. Step S02 may include sub-step (i) forming a patterned mask (not shown) on the nitride layer 13 shown in FIG. 2 to partially expose the nitride layer 13, sub-step (ii) etching the nitride layer 13, the pad oxide layer 12, and the first substrate portion 113a of the upper semiconductor layer 113 through the patterned mask to form shallow trenches (not shown), sub-step (iii) filling the shallow trenches with an oxide-based material layer, for example, but not limited to, silicon oxide or other suitable oxide-based materials, and sub-step (iv) removing an excess portion of the oxide-based material layer on the etched nitride layer 13 by a suitable planarization process, for example, but not limited to, chemical mechanical polish (CMP) or other suitable planarization processes. The patterned mask may include a photoresist material or other suitable mask materials, and may be formed by coating a photoresist layer, soft-baking the photoresist layer, exposing the photoresist layer through a photomask, post-exposure baking the photoresist layer, and developing the photoresist layer, followed by hard-baking the photoresist layer to thereby obtain the patterned mask.

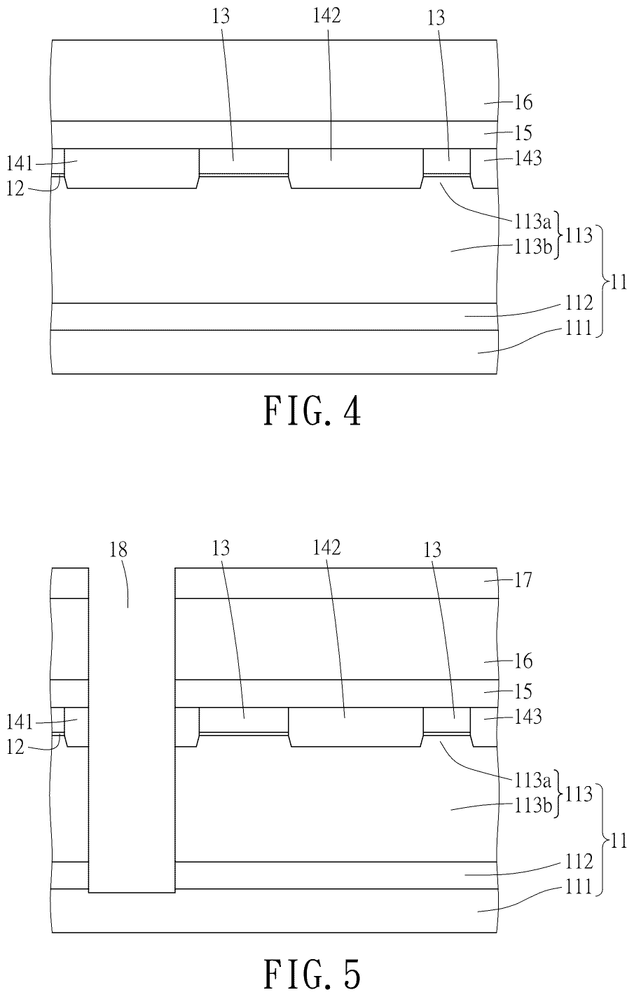

Referring to FIG. 1 and the example illustrated in FIG. 4, the method 100A then proceeds to step S03, where a nitride layer 15 and a dielectric layer 16 are sequentially formed on the structure shown in FIG. 3. The nitride layer 15 is formed on the etched nitride layer 13 and the STI structures 141, 142, 143 opposite to the upper semiconductor layer 113. In some embodiments, the nitride layer 15 may include, for example, but not limited to, silicon nitride. Other suitable materials for forming the nitride layer 15 are also within the contemplated scope of the present disclosure. In some embodiments, the nitride layer 15 may be formed by a suitable deposition process, for example, but not limited to, CVD, PVD, or ALD. Other suitable processes for forming the nitride layer 15 are also within the contemplated scope of the present disclosure. The dielectric layer 16 is formed on the nitride layer 15 opposite to the etched nitride layer 13. In some embodiments, the dielectric layer 16 may include, for example, but not limited to, undoped silicate glass (USG). Other suitable dielectric materials for forming the dielectric layer 16 are also within the contemplated scope of the present disclosure. In some embodiments, the dielectric layer 16 may be formed by a suitable deposition process, for example, but not limited to, CVD, PVD, or ALD. Other suitable processes for forming the dielectric layer 16 are also within the contemplated scope of the present disclosure. In some embodiments, the dielectric layer 16 may have a thickness ranging from about 5000 Å to about 8000 Å.

Referring to FIG. 1 and the example illustrated in FIG. 5, the method 100A then proceeds to step S04, where the dielectric layer 16, the nitride layer 15, the STI structure 141, the upper semiconductor layer 113, the buried insulation layer 112, and the lower semiconductor layer 111 are patterned through a patterned mask 17 to form a deep trench 18. In this step, the deep trench 18 extends through the dielectric layer 16, the nitride layer 15, the STI structure 141, a second substrate portion 113b of the upper semiconductor layer 113, and the buried insulation layer 112, into the lower semiconductor layer 111. Step S04 may be performed by a photolithography process, which includes an etching process. The material and process for forming the patterned mask 17 are similar to those of the patterned mask as described in step S02, and thus details thereof are omitted for the sake of brevity. After formation of the deep trench 18, the patterned mask 17 may be removed by a suitable removal process.

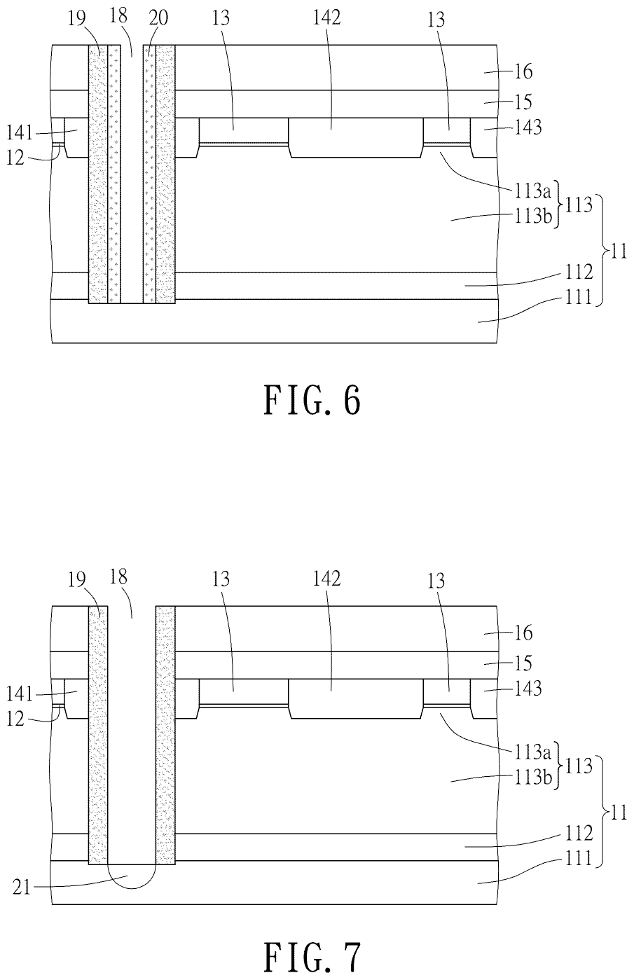

Referring to FIG. 1 and the example illustrated in FIG. 6, the method 100A then proceeds to step S05, where an isolation layer 19 and a protective layer 20 are sequentially formed. Step S05 includes sub-steps (i) to (iii).

In sub-step (i), an isolating material layer (not shown) for forming the isolation layer 19 is conformally formed on the structure shown in FIG. 5. In some embodiments, the isolating material layer may be made of an oxide-based material, for example, but not limited to, silicon oxide or silicon oxynitride. Other suitable oxide-based materials for forming the isolating material layer are also within the contemplated scope of the present disclosure. In some embodiments, the isolating material layer may be formed by a suitable deposition process, for example, but not limited to, CVD or PVD. Other suitable processes for forming the isolating material layer are also within the contemplated scope of the present disclosure. In some embodiments, the isolating material layer may have a thickness greater than about 2000 Å.

In sub-step (ii), a protective material layer (not shown) for forming the protective layer 20 is conformally formed on the structure obtained after sub-step (i). In some embodiments, the protective material layer may be made of a nitride-based material, for example, but not limited to, silicon nitride. Other suitable nitride-based materials for forming the protective material layer are also within the contemplated scope of the present disclosure. In some embodiments, the protective material layer may be formed by a suitable deposition process, for example, but not limited to, CVD or PVD. Other suitable processes for forming the protective material layer are also within the contemplated scope of the present disclosure. In some embodiments, the protective material layer may have a thickness ranging from about 200 Å to about 500 Å.

In sub-step (iii), an anisotropic etching process is performed on the structure obtained after sub-step (ii) to sequentially remove horizontal portions of the protective material layer on the dielectric layer 16 and a bottom surface of the deep trench 18, and horizontal portions of the isolating material layer on the dielectric layer 16 and the bottom surface of the deep trench 18. The bottom surface of the deep trench 18 may be defined by a portion of an upper surface of the lower semiconductor layer 111. In some embodiments, in the anisotropic etching process, an etchant gas used for removing the horizontal portions of the protective material layer may be different from an etchant gas used for removing the horizontal portions of the isolating material layer. In some embodiments, the etchant gas used for removing the horizontal portions of the protective material layer may be, for example, but not limited to, tetrafluoromethane gas, fluoromethane gas, difluoromethane gas, or combinations thereof. Other suitable etchant gases for removing the horizontal portions of the protective material layer are also within the contemplated scope of the present disclosure. In some embodiments, the etchant gas used for removing the horizontal portions of the isolating material layer may be, for example, but not limited to, octafluorocyclobutane gas, hexafluorobutadiene gas, or a combination thereof. Other suitable etchant gases for removing the horizontal portions of the isolating material layer are also within the contemplated scope of the present disclosure. In some embodiments, a dilute gas may be used together with the etchant gas used for removing the horizontal portions of the isolating material layer, so as to improve uniformity of distribution of the etchant gas and to increase an etching rate of the etchant gas. In some embodiments, the dilute gas may be, for example, but not limited to, an oxygen gas, an argon gas, or a combination thereof. Other suitable dilute gases are also within the contemplated scope of the present disclosure. After this sub-step, a remaining portion (i.e., a vertical portion) of the isolating material layer may be referred to as the isolation layer 19, and a remaining portion (i.e., a vertical portion) of the protective material layer may be referred to as the protective layer 20. The isolation layer 19 is disposed on two opposite trench-defining sidewalls of the deep trench 18. The protective layer 20 is disposed on the isolation layer 19 and in the deep trench 18.

In this step, by having the protective material layer formed on the isolating material layer, the vertical portion of the isolating material layer may not be damaged in the anisotropic etching process (i.e., sub-step (iii)) due to protection conferred by the protective material layer. The isolation layer 19 thus formed may have a cross section that has a rectangular shape. If the thickness of the protective material layer is less than 200 Å, the vertical portion of the isolating material layer may not be protected effectively by the protective material layer, and thus may be damaged in the anisotropic etching process. If the thickness of the protective material layer is greater than 500 Å, a process cost for manufacturing the semiconductor structure 200A (shown in FIG. 9A or 9B) may be increased.

Referring to FIG. 1 and the example illustrated in FIG. 7, the method 100A then proceeds to step S06, where the protective layer 20 is removed. Step S06 may be performed by a suitable etching process. In some embodiments, the etching process may be, for example, but not limited to, a wet etching process. In this case, an etchant used in the wet etching process may be, for example, but not limited to, phosphoric acid. Other suitable etching processes are also within the contemplated scope of the present disclosure. In some embodiments, the protective layer 20 may not be removed.

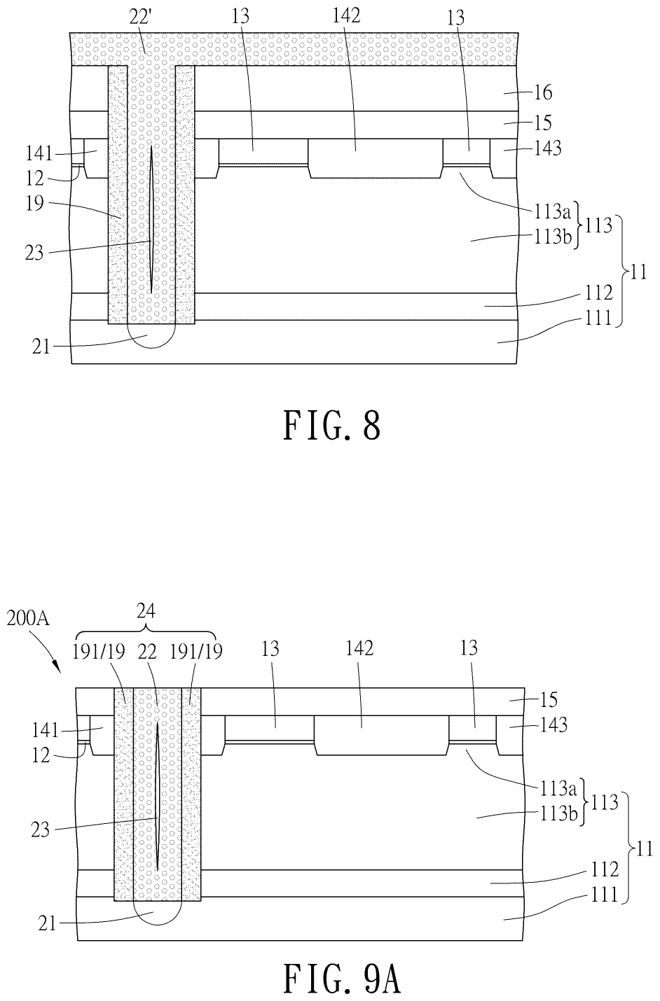

In some embodiments, after removal of the protective layer 20 (i.e., step S06), a doping region 21 may be formed in the lower semiconductor layer 111 by a suitable doping process, for example, but not limited to, ion implantation. Other suitable doping processes are also within the contemplated scope of the present disclosure. The doping region 21 may be formed using a P-type dopant (e.g., boron, aluminum, or gallium) in some embodiments, and may be formed using an N-type dopant (e.g., phosphorous, antimony, or arsenic) in other embodiments. Other suitable P-type dopants or N-type dopants are also within the contemplated scope of the present disclosure. The doping region 21 is used to enhance electrical connection between a conduction layer 22 (shown in FIG. 9, and formed from a conductive material layer 22′ shown in FIG. 8) and the lower semiconductor layer 111.

Referring to FIG. 1 and the example illustrated in FIG. 8, the method 100A then proceeds to step S07, where the conductive material layer 22′ is formed over the structure shown in FIG. 7. In some embodiments, the conductive material layer 22′ may include, for example, but not limited to, polysilicon. Other suitable materials for forming the conductive material layer 22′ are also within the contemplated scope of the present disclosure. In some embodiments, the conductive material layer 22′ may be formed by a suitable deposition process, for example, but not limited to, CVD, PVD, or ALD. Other suitable deposition processes for forming the conductive material layer 22′ are also within the contemplated scope of the present disclosure. In the deep trench 18 (see FIG. 7), the conductive material layer 22′ is connected to the lower semiconductor layer 111. In formation of the conductive material layer 22′ that fills the deep trench 18, a seam 23 may be formed in the conductive material layer 22′. In some embodiments, the doping region 21 and the conductive material layer 22′ may have an identical doping type.

Referring to FIG. 1 and the examples illustrated in FIGS. 9A and 9B, the method 100A then proceeds to step S08, where a planarization process is performed to remove an upper portion of the conductive material layer 22′, the dielectric layer 16, and an upper portion of the isolation layer 19. In some embodiments, the planarization process may be, for example, but not limited to, CMP. Other suitable planarization processes are also within the contemplated scope of the present disclosure. After step S08, a remaining portion of the conductive material layer 22′ (see FIG. 8) is referred to as the conduction layer 22, and the isolation layer 19 and the conduction layer 22 together form a deep trench isolation (DTI) structure 24. Referring to FIG. 9A, the isolation layer 19 includes two isolation portions 191 respectively disposed at two opposite sides of the conduction layer 22 so as to separate the conduction layer 22 from the first and second substrate portions 113a, 113b of the upper semiconductor layer 113. Referring to FIG. 9B, if the protective layer 20 is not removed (i.e., omitting step S06), the DTI structure 24 may further include the protective layer 20. In this case, the protective layer 20 may include two protective layer portions 201, and each of the protective layer portions 201 is disposed between the conduction layer 22 and a corresponding one of the isolation portions 191 of the isolation layer 19.

After step S09, the semiconductor structure 200A is obtained. In some embodiments, a portion of the isolation layer 19 and a portion of the conduction layer 22 may be etched back in a subsequent etching process. In some embodiments, an upper surface of each of the etched isolation layer 19 and the etched conduction layer 22 may be flush with an upper surface of the STI structure 141. In some embodiments, after etching back of the isolation layer 19 and the conduction layer 22, the nitride layers 13, 15 may be removed.

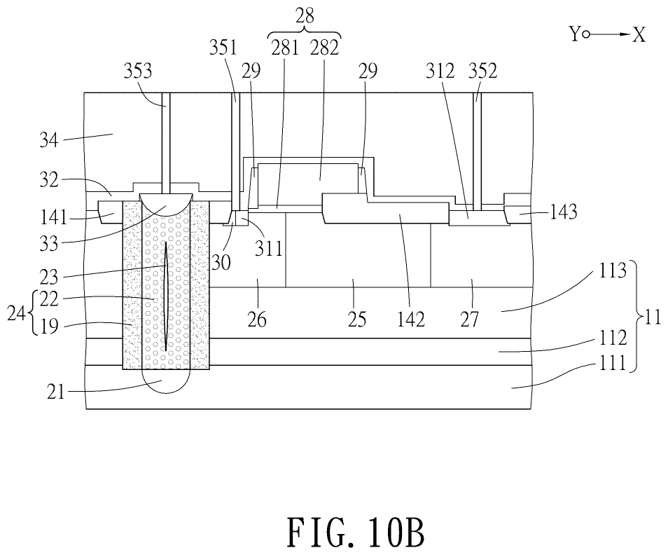

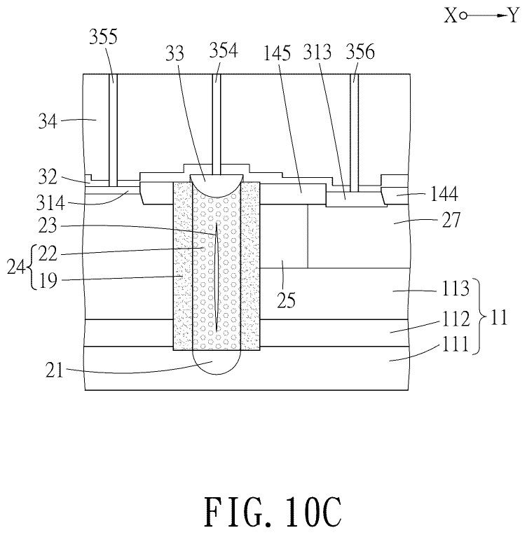

FIGS. 10A to 10C illustrate a MOS device in accordance with some embodiments. FIG. 10A is a simplified top view of the MOS device. FIG. 10B illustrates a schematic view taken along a first direction (an X direction shown in FIG. 10A). FIG. 10C illustrates a schematic view taken along a second direction (a Y direction shown in FIG. 10A) transverse to the first direction. The MOS device may include the DTI structure 24 shown in FIG. 9A or 9B, a plurality of well regions 25, 26, 27, a gate structure 28, two gate spacers 29, a doped region 30, a plurality of source/drain regions 311, 312, 313, 314, a contact etch stop layer (CESL) 32, an inter-layer dielectric (ILD) layer 34, and a plurality of contact vias 351, 352, 353, 354, 355, 356.

In some embodiments, the well regions 25, 26, 27 may be formed by a suitable process, for example, but not limited to, ion implantation. Other suitable processes for forming the well regions 25, 26, 27 are also within the contemplated scope of the present disclosure. In some embodiments, each of the well regions 25, 27 has a first type conductivity (i.e., each of the well regions 25, 27 is a first-type well region), and may be doped using an N-type dopant (e.g., phosphorous, antimony, or arsenic) for an N-type MOS device, or may be doped using a P-type dopant (e.g., boron, aluminum, or gallium) for a P-type MOS device. In some embodiments, the well region 26 is a second-type well region that has a second type conductivity, which is different from the first type conductivity of the well region 25 (or the well region 27). That is, when the first type conductivity of each of the well regions 25, 27 is N-type, the second type conductivity of the well region 26 is P-type, and vice versa. In some embodiments, the well region 25 may be a high voltage N-well (HVNW) region, the well region 26 may be a 5V P-well (5VPW) region, and the well region 27 may be a 5V N-well (5VNW) region.

The gate structure 28 includes a gate dielectric 281 and a gate electrode 282. In some embodiments, the gate dielectric 281 may include, for example, but not limited to, silicon oxide. Other suitable materials for the gate dielectric 281 are also within the contemplated scope of the present disclosure. The gate electrode 282 is disposed on the gate dielectric 281 and a portion of the STI structure 142. In some embodiments, the gate electrode 282 may include, for example, but not limited to, polysilicon. Other suitable materials for the gate electrode 282 are also within the contemplated scope of the present disclosure. In some embodiments, the gate structure 28 may be formed by (i) forming a dielectric layer (not shown) on the semiconductor substrate 11 by, for example, but not limited to, thermally oxidizing the upper semiconductor layer 113 in an oxygen-containing atmosphere, or by other suitable processes, (ii) depositing an electrode layer (not shown) over the dielectric layer by a suitable deposition process, for example, but not limited to, CVD, PVD, or ALD, and (iii) patterning the dielectric layer and the electrode layer.

The gate spacers 29 are formed at two opposite sides of the gate structure 28. In some embodiments, formation of the gate spacers 29 may include sub-step (i) depositing a spacer material layer (not shown) over the structure obtained after formation of the gate structure 28 by a suitable deposition process, for example, but not limited to, CVD, PVD, ALD, or other suitable deposition processes, and sub-step (ii) anisotropically etching (e.g., a dry etching process or other suitable etching processes) the spacer material layer, so as to obtain the gate spacers 29. In some embodiments, the spacer material layer for forming the gate spacers 29 may include, for example, but not limited to, silicon oxide or silicon nitride. Other suitable materials for the spacer material layer are also within the contemplated scope of the present disclosure.

Each of the source/drain regions 311, 312, 313, 314 has the first type conductivity while the doped region 30 has the second type conductivity. The doped region 30 is formed in the well region 26 at a position distal from the gate structure 28 and adjacent to the STI structure 141. The source/drain region 311 is formed in the well region 26 at a position proximate to the gate structure 28. The source/drain region 312 is formed in the well region 27 at a position between the STI structure 142 and the STI structure 143. The source/drain region 313 is formed in the well region 27 at a position between a STI structure 144 and a STI structure 145. The source/drain region 314 is formed in the upper semiconductor layer 113 at a position proximate to the STI structure 145. The doped region 30 and the source/drain regions 311, 312, 313, 314 may be formed by a suitable process, for example, but not limited to, ion implantation or other suitable processes.

The CESL 32 is formed on the upper semiconductor layer 113, the STI structures 141, 142, 143, 144, 145, the source/drain regions 311, 312, 313, 314, the gate structure 28, and the gate spacers 29. In some embodiments, the CESL 32 may include, for example, but not limited to, silicon nitride. Other suitable materials for forming the CESL 32 are also within the contemplated scope of the present disclosure. In some embodiments, the CESL 32 may be formed by a suitable deposition process, for example, but not limited to, CVD or ALD. Other suitable deposition processes for forming the CESL 32 are also within the contemplated scope of the present disclosure.

In some embodiments, before formation of the CESL 32, a doping region 33 may be formed between the conduction layer 22 and the CESL 32. The process and the dopant for forming the doping region 33 may be the same as or similar to those for forming the doping region 21, and thus details thereof are omitted for the sake of brevity.

The ILD layer 34 is formed on the CESL 32. In some embodiments, the ILD layer 34 may include, for example, but not limited to, USG, doped silicon oxide, borophosphosilicate glass (BPSG), phosphosilicate glass (PSG), fused silica glass (FSG), boron doped silicon glass (BSG), or tetraethylorthosilicate (TEOS) oxide. Other suitable materials for forming the ILD layer 34 are also within the contemplated scope of the present disclosure. In some embodiments, the ILD layer 34 may be formed by a suitable deposition process, for example, but not limited to, CVD or spin-on coating. Other suitable deposition processes for forming the ILD layer 34 are also within the contemplated scope of the present disclosure.

The contact vias 351, 352, 353, 354, 355, 356 are formed in the CESL 32 and the ILD layer 34. In some embodiments, the contact vias 351, 352, 353, 354, 355, 356 may include, for example, but not limited to, tungsten. Other suitable materials for forming the contact vias 351, 352, 353, 354, 355, 356 are also within the contemplated scope of the present disclosure. The process for forming the contact vias 351, 352, 353, 354, 355, 356 may be the same as or similar to that for forming the STI structures 141, 142, 143 as described in step S02, and thus details thereof are omitted for the sake of brevity. In some embodiments, the contact via 351 is electrically connected to the doped region 30 and the source/drain region 311, the contact via 352 is electrically connected to the source/drain region 312, the contact vias 353, 354 are electrically connected to the doping region 33, the contact via 355 is electrically connected to the source/drain region 314, and the contact via 356 is electrically connected to the source/drain region 313.

As shown in FIG. 10A, the MOS device includes a high voltage region 36 disposed on the well region 27, and a low voltage region 37 surrounding the DTI structure 24. Because the isolation layer 19 or an isolation structure (i.e., a combination of the isolation layer 19 and the protective layer 20) of the DTI structure 24 has a uniform configuration and a sufficient width (i.e., the thickness of the isolating material layer), the DTI structure 24 can efficiently prevent charged carriers in the high voltage region 36 from passing through the DTI structure 24 to the low voltage region 37 when the MOS device is operated under a high voltage (e.g., about 120 V). Therefore, leakage and electrical breakdown can be avoided in the MOS device. It is noted that if the width of each of the isolation portions 191 of the isolation layer 19 is less than 2000 Å, the charged carriers may pass through the DTI structure 24 into the low voltage region 37 when the MOS device is operated under a high voltage (e.g., about 120 V), resulting in leakage and electrical breakdown.

A semiconductor structure of this disclosure includes a robust DTI structure including a conduction layer and an isolation layer that has a uniform configuration and a sufficient width. In a process for manufacturing the semiconductor structure, before formation of the isolation layer (formed from an isolating material layer), a protective material layer is formed on the isolating material layer to protect the isolating material layer from being damaged in a subsequent etching process. When the semiconductor structure is operated under a high voltage, the DTI structure can prevent charged carriers in a high voltage region of the semiconductor structure from passing therethrough and migrating to a low voltage region of the semiconductor structure, which can further avoid leakage and electrical breakdown in the semiconductor structure.

In accordance with some embodiments of the present disclosure, a method for manufacturing a semiconductor structure includes: forming a trench in a semiconductor substrate; forming an isolating material layer on the semiconductor substrate and in the trench; forming a protective material layer on the isolating material layer and in the trench; removing horizontal portions of the protective material layer to form a protective layer laterally covering the isolating material layer and to expose horizontal portions of the isolating material layer from the protective layer; removing the horizontal portions of the isolating material layer to form an isolation layer that laterally covers the semiconductor substrate and that is disposed between the protective layer and the semiconductor substrate; and forming a conductive material layer to fill the trench.

In accordance with some embodiments of the present disclosure, the isolating material layer has a thickness greater than about 2000 Å.

In accordance with some embodiments of the present disclosure, the protective material layer has a thickness ranging from about 200 Å to about 500 Å.

In accordance with some embodiments of the present disclosure, the horizontal portions of the protective material layer are removed by an anisotropic etching process.

In accordance with some embodiments of the present disclosure, an etchant gas used in the anisotropic etching process is tetrafluoromethane gas, fluoromethane gas, difluoromethane gas, or combinations thereof.

In accordance with some embodiments of the present disclosure, the horizontal portions of the isolating material layer are removed by an anisotropic etching process.

In accordance with some embodiments of the present disclosure, an etchant gas used in the anisotropic etching process is octafluorocyclobutane gas, hexafluorobutadiene gas, or a combination thereof.

In accordance with some embodiments of the present disclosure, a dilute gas is used together with the etchant gas in the anisotropic etching process for removing the horizontal portions of the isolating material layer. The dilute gas includes oxygen gas, argon gas, or a combination thereof.

In accordance with some embodiments of the present disclosure, a method for manufacturing a semiconductor structure includes: forming a shallow trench isolation structure at a first substrate portion of a semiconductor substrate; forming a trench which penetrates the shallow trench isolation structure, and which extends through a second substrate portion of the semiconductor substrate, the second substrate portion being located beneath the first substrate portion; forming an isolating material layer on the semiconductor substrate and the shallow trench isolation structure and in the trench; forming a protective material layer on the isolating material layer and in the trench; removing horizontal portions of the protective material layer to form a protective layer laterally covering the isolating material layer and to expose horizontal portions of the isolating material layer from the protective layer; removing the horizontal portions of the isolating material layer to form an isolation layer that laterally covers the semiconductor substrate and the shallow trench isolation structure and that is disposed between the protective layer and the semiconductor substrate; and forming a conductive material layer to fill the trench.

In accordance with some embodiments of the present disclosure, the method for manufacturing the semiconductor structure further includes, after removal of the horizontal portions of the isolating material layer and before formation of the conductive material layer, removing the protective layer.

In accordance with some embodiments of the present disclosure, the protective layer is removed by a wet etching process.

In accordance with some embodiments of the present disclosure, an etchant used in the wet etching process includes phosphoric acid.

In accordance with some embodiments of the present disclosure, the method for manufacturing the semiconductor structure further includes, performing a planarization process to form the conductive material layer into a conduction layer laterally covered by the isolation layer.

In accordance with some embodiments of the present disclosure, the isolation layer includes two isolation portions respectively disposed at two opposite sides of the conduction layer to separate the conduction layer from the first substrate portion and the second substrate portion. Each of the two isolation portions has a cross section of a rectangular shape.

In accordance with some embodiments of the present disclosure, a semiconductor structure includes a semiconductor substrate, a shallow trench isolation (STI) structure, and a deep trench isolation (DTI) structure. The STI structure is located at a first substrate portion of the semiconductor substrate. The DTI structure is located in the STI structure and extends through a second substrate portion of the semiconductor substrate which is located beneath the first substrate portion. The DTI structure includes a conduction layer and an isolation layer that is disposed to separate the conduction layer from the first substrate portion and the second substrate portion, and that has a cross section of a rectangular shape.

In accordance with some embodiments of the present disclosure, the isolation layer includes an oxide-based material and the conduction layer includes polysilicon.

In accordance with some embodiments of the present disclosure, the DTI structure further includes a protective layer disposed between the isolation layer and the conduction layer.

In accordance with some embodiments of the present disclosure, the protective layer includes a nitride-based material.

In accordance with some embodiments of the present disclosure, the isolation layer includes two isolation portions respectively disposed at two opposite sides of the conduction layer, and the protective layer includes two protective layer portions. Each of the two protective layer portions is disposed between the conduction layer and a corresponding one of the two isolation portions.

In accordance with some embodiments of the present disclosure, the semiconductor substrate includes a lower semiconductor layer, a buried insulation layer disposed on the lower semiconductor layer, and an upper semiconductor layer disposed on the buried insulation layer opposite to the lower semiconductor layer. The upper semiconductor layer includes the first substrate portion and the second substrate portion. The DTI structure extends through the STI structure, the upper semiconductor layer and the buried insulation layer into the lower semiconductor layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a trench in a semiconductor substrate;
forming an isolating material layer on the semiconductor substrate and in the trench;
forming a protective material layer on the isolating material layer and in the trench;
removing horizontal portions of the protective material layer to form a protective layer laterally covering the isolating material layer and to expose horizontal portions of the isolating material layer from the protective layer;
removing the horizontal portions of the isolating material layer to form an isolation layer that laterally covers the semiconductor substrate and that is disposed between the protective layer and the semiconductor substrate; and
forming a conductive material layer to fill the trench.

2. The method as claimed in claim 1, wherein the isolating material layer has a thickness greater than 2000 Å.

3. The method as claimed in claim 1, wherein the protective material layer has a thickness ranging from 200 Å to 500 Å.

4. The method as claimed in claim 1, wherein the horizontal portions of the protective material layer are removed by an anisotropic etching process.

5. The method as claimed in claim 4, wherein an etchant gas used in the anisotropic etching process is tetrafluoromethane gas, fluoromethane gas, difluoromethane gas, or combinations thereof.

6. The method as claimed in claim 1, wherein the horizontal portions of the isolating material layer are removed by an anisotropic etching process.

7. The method as claimed in claim 6, wherein an etchant gas used in the anisotropic etching process is octafluorocyclobutane gas, hexafluorobutadiene gas, or a combination thereof.

8. The method as claimed in claim 7, wherein a dilute gas is used together with the etchant gas in the anisotropic etching process for removing the horizontal portions of the isolating material layer, the dilute gas including oxygen gas, argon gas, or a combination thereof.

9. A method for manufacturing a semiconductor structure, comprising:
forming a shallow trench isolation structure at a first substrate portion of a semiconductor substrate;
forming a trench which penetrates the shallow trench isolation structure, and which extends through a second substrate portion of the semiconductor substrate, the second substrate portion being located beneath the first substrate portion;
forming an isolating material layer on the semiconductor substrate and the shallow trench isolation structure and in the trench;
forming a protective material layer on the isolating material layer and in the trench;
removing horizontal portions of the protective material layer to form a protective layer laterally covering the isolating material layer and to expose horizontal portions of the isolating material layer from the protective layer;
removing the horizontal portions of the isolating material layer to form an isolation layer that laterally covers the semiconductor substrate and the shallow trench isolation structure and that is disposed between the protective layer and the semiconductor substrate; and
forming a conductive material layer to fill the trench.

10. The method as claimed in claim 9, further comprising, after removal of the horizontal portions of the isolating material layer and before formation of the conductive material layer, removing the protective layer.

11. The method as claimed in claim 10, wherein the protective layer is removed by a wet etching process.

12. The method as claimed in claim 11, wherein an etchant used in the wet etching process includes phosphoric acid.

13. The method as claimed in claim 10, further comprising performing a planarization process to form the conductive material layer into a conduction layer laterally covered by the isolation layer.

14. The method as claimed in claim 13, wherein the isolation layer includes two isolation portions respectively disposed at two opposite sides of the conduction layer to separate the conduction layer from the first substrate portion and the second substrate portion, each of the two isolation portions having a cross section of a rectangular shape.

15. A semiconductor structure comprising:
a semiconductor substrate;
a shallow trench isolation (STI) structure located at a first substrate portion of the semiconductor substrate; and
a deep trench isolation (DTI) structure located in the STI structure and extending through a second substrate portion of the semiconductor substrate which is located beneath the first substrate portion, the DTI structure including a conduction layer and an isolation layer that is disposed to separate the conduction layer from the first substrate portion and the second substrate portion, and that has a cross section of a rectangular shape.

16. The semiconductor structure as claimed in claim 15, wherein the isolation layer includes an oxide-based material and the conduction layer includes polysilicon.

17. The semiconductor structure as claimed in claim 15, wherein the DTI structure further includes a protective layer disposed between the isolation layer and the conduction layer.

18. The semiconductor structure as claimed in claim 17, wherein the protective layer includes a nitride-based material.

19. The semiconductor structure as claimed in claim 17, wherein the isolation layer includes two isolation portions respectively disposed at two opposite sides of the conduction layer, and the protective layer includes two protective layer portions, each of the two protective layer portions being disposed between the conduction layer and a corresponding one of the two isolation portions.

20. The semiconductor structure as claimed in claim 19, wherein the semiconductor substrate includes a lower semiconductor layer, a buried insulation layer disposed on the lower semiconductor layer, and an upper semiconductor layer disposed on the buried insulation layer opposite to the lower semiconductor layer, the upper semiconductor layer including the first substrate portion and the second substrate portion, the DTI structure extending through the STI structure, the upper semiconductor layer and the buried insulation layer into the lower semiconductor layer.
